(19) United States
(12) Patent Application Publication
(10) Pub. No.: US 2024/0105704 A1
(43) Pub. Date: Mar. 28, 2024

(54) 3D Package with Chip-on-Reconstituted Wafer or Reconstituted Wafer-on-Reconstituted Wafer Bonding

(71) Applicant: Apple Inc., Cupertino, CA (US)

(72) Inventors: Chonghua Zhong, Cupertino, CA (US); Jiongxin Lu, Cupertino, CA (US); Kunzhong Hu, Cupertino, CA (US); Jun Zhai, Cupertino, CA (US); Sanjay Dabral, Cupertino, CA (US)

(21) Appl. No.: 18/458,918

(22) Filed: Aug. 30, 2023

Related U.S. Application Data
(63) Continuation-in-part of application No. 18/178,820, filed on Mar. 6, 2023.
Application No. 18/178,820 is a continuation-in-part of application No. 17/934,346, filed on Sep. 22, 2022.

(51) Int. Cl. H01L 25/18; G02B 6/43; H01L 23/00

(52) U.S. Cl. CPC H01L 25/18; G02B 6/43; H01L 24/08; H01L 28/10; H01L 28/40; H01L 2224/08145; H01L 2224/08225

(57) ABSTRACT

Semiconductor packages formed utilizing wafer reconstitution and optionally including an integrated heat spreader and methods of fabrication are described. In an embodiment, a semiconductor package includes a first package level, a second package level including one or more second-level chiplets. A heat spreader may be bonded to the second package level with a metallic layer, which may include one or more intermetallic compounds formed by transient liquid phase bonding. The chiplets within the first and/or second package levels may optionally be connected with one or more optical interconnect paths.

### RELATED APPLICATIONS

This application is a continuation in part of co-pending U.S. application Ser. No. 18/178,820 filed Mar. 6, 2023, which is a continuation in part of co-pending U.S. application Ser. No. 17/934,346 filed Sep. 22, 2022, both which are herein incorporated by reference.

### BACKGROUND

### Field

Embodiments described herein relate to integrated circuit (IC) manufacture, and the thermal performance of semiconductor packages.

### Background Information

The current market demand for portable and mobile electronic devices such as mobile phones, personal digital assistants (PDAs), digital cameras, portable players, gaming, and other mobile devices requires the integration of more performance and features into increasingly smaller spaces. As a result, various multiple-die packaging solutions such as system in package (SiP) and package on package (PoP) have become more popular to meet the demand for higher die/component density devices.

There are many different possibilities for arranging multiple dies in an SiP. For example, integration of dies in SiP structures has evolved into 2.5D solutions and 3D solutions. In 2.5D solutions the multiple dies may be flip chip bonded on an interposer that includes through vias as well as fan out wiring. In various 3D solutions multiple dies may be stack on top of one another and connected with off-chip wire bonds or solder bumps. Wafer on wafer (WoW) or chip on wafer (CoW) techniques can also be utilized in the various 2.5D and 3D solutions to directly bond the dies with high density connections. For example, thermocompression bonding can be used to achieve metal-metal bonds, and hybrid bonding can be used to form oxide-oxide bonds along with the metal-metal bonds.

### SUMMARY

Embodiments describe various semiconductor packages with integrated heat spreaders, such as permanent silicon substrate carriers. In an embodiment, a semiconductor package includes a first package level, a second package level including one or more second-level chiplets, and a heat spreader bonded to the second package level with a metallic layer. For example, the heat spreader may be formed from a silicon substrate and bonded to the second package level with transient liquid phase bonding (TLP). After singulation the semiconductor package may include straight package sidewalls spanning the first package level, the second package level, the metallic layer, and the heat spreader.

Embodiments additionally describe various semiconductor package fabrication sequences that integrated wafer reconstitution with CoW and WoW bonding to create 3D semiconductor packages with hybrid bonding vertically connecting the dies, or chiplets.

### BRIEF DESCRIPTION OF THE DRAWINGS

FIGS. 1A-1B are schematic cross-sectional side view illustrations of a semiconductor package with integrated heat spreader in accordance with embodiments.

FIGS. 2-3 are schematic cross-sectional side view illustrations of multiple bonding layers prior to bonding a heat spreader with a second package level in accordance with embodiments.

FIGS. 4A-4B are schematic cross-sectional side view illustration of a heat spreader bonded to a second package level with a metallic layer in accordance with embodiments.

FIGS. 5A-5E are schematic cross-sectional side view illustrations of a method of forming a semiconductor package with CoW chiplet bonding and an integrated heat spreader in accordance with an embodiment.

FIGS. 6A-B are schematic cross-sectional side view illustrations of a method of forming a reconstituted first package level in accordance with an embodiment.

FIGS. 7A-7C are schematic cross-sectional side view illustrations of a method of forming a reconstituted second package level with integrated heat spreader in accordance with an embodiment.

FIG. 8 is a schematic cross-sectional side view illustration of reconstituted WoW bonding with an integrated heat spreader in accordance with and embodiment.

FIG. 9 is a schematic cross-sectional side view illustration of a semiconductor package with intermediate interposer and integrated heat spreader in accordance with an embodiment.

FIG. 10 is schematic cross-sectional side view illustration of a semiconductor package with an integrated heat spreader bonded to a silicon gap fill material in accordance with an embodiment.

FIGS. 11-12 are schematic cross-sectional side view illustrations of semiconductor packages formed with chip-on-reconstituted wafer or reconstituted wafer-on-reconstituted wafer processing sequences in accordance with embodiments.

FIG. 13 is a schematic cross-sectional side view illustration of a semiconductor package formed with a chip-on-reconstituted wafer processing sequence in accordance with an embodiment.

FIG. 14 is a process flow of a semiconductor package formed with a chip-on-reconstituted wafer processing sequence in accordance with an embodiment.

FIGS. 15A-15D are schematic cross-sectional side view illustrations of a semiconductor package formed with a chip-on-reconstituted wafer processing sequence in accordance with an embodiment.

FIG. 16 is a process flow of a semiconductor package formed with a reconstituted wafer-on-reconstituted wafer processing sequence in accordance with an embodiment.

FIGS. 17A-17B are schematic cross-sectional side view illustrations of a semiconductor package formed with a reconstituted wafer-on-reconstituted wafer processing sequence in accordance with an embodiment.

FIG. 18 is a process flow of a semiconductor package formed with a chip-on-reconstituted wafer processing sequence in accordance with an embodiment.

FIGS. 19A-19D are schematic cross-sectional side view illustrations of a semiconductor package formed with a chip-on-reconstituted wafer processing sequence in accordance with an embodiment.

FIG. 20 is a schematic cross-sectional side view illustration of a multi-chip module system including a semiconductor package with integrated heat spreader in accordance with an embodiment.

FIGS. 21-29 are schematic cross-sectional side view illustrations of semiconductor package structures with optical interconnects in accordance with embodiments.

FIG. 30 is a schematic cross-sectional side view illustration of a second-level chiplet including multiple converters and optical vias in accordance with an embodiment.

### DETAILED DESCRIPTION

Embodiments describe semiconductor package structures including multiple package levels and a heat spreader that is bonded to an upper package level with a metallic layer. For example, transient liquid phase bonding may be used to bond a silicon carrier wafer to a package level during fabrication. Upon singulation, the semiconductor package includes package sidewalls that span the multiple chip layers, the metallic layer, and the heat spreader formed by the bonded and singulated carrier wafer.

In one aspect, it has been observed that thermal performance for chip-on-wafer (CoW) and wafer-on-wafer (WoW) semiconductor package structures for high performance computing applications is important for both thermal dissipation and performance boost. For example, a three dimensional integrated circuit (3DIC) semiconductor package structure may include multiple package levels including one or more chiplets that have been direct bonded to another package level using thermal compression, fusion bonding or hybrid bonding. While such packaging techniques can result in a high density of connections, and fine bond pad pitch, it has been observed that these techniques can also result in package structures with closely assembled chiplets with limited avenues for heat dissipation.

In accordance with embodiments, silicon substrates may be integrated into the CoW or WoW packaging sequence as a carrier substrate and/or heat spreader. Furthermore, it has been observed that bonding of a silicon substrate to an underlying structure using an oxide layer, such as with fusion bonding, provides limited thermal performance as a heat spreader due to the low thermal conductivity of the oxide layer. In accordance with embodiments, transient liquid phase (TLP) bonding can be utilized to bond the silicon substrate where the resultant intermetallic compound(s) have a high thermal conductivity and high melting temperature that can withstand downstream thermal processes. TLP bonding can additionally be performed at significantly lower temperatures with higher throughput per hour compared to fusion bonding, and create a strong bond.

Embodiments additionally describe various semiconductor package fabrication sequences that integrated wafer reconstitution with CoW and WoW bonding to create 3D semiconductor packages with hybrid bonding vertically connecting the dies, or chiplets. This can facilitate high bandwidth die-to-die (chiplet-to-chiplet) connection. Reconstitution additionally provides flexibility of bottom die (chiplet) sizes, and allows the bottom dies to be either face up or face down.

In various embodiments, description is made with reference to figures. However, certain embodiments may be practiced without one or more of these specific details, or in combination with other known methods and configurations. In the following description, numerous specific details are set forth, such as specific configurations, dimensions and processes, etc., in order to provide a thorough understanding of the embodiments. In other instances, well-known semiconductor processes and manufacturing techniques have not been described in particular detail in order to not unnecessarily obscure the embodiments. Reference throughout this specification to “one embodiment” means that a particular feature, structure, configuration, or characteristic described in connection with the embodiment is included in at least one embodiment. Thus, the appearances of the phrase “in one embodiment” in various places throughout this specification are not necessarily referring to the same embodiment. Furthermore, the particular features, structures, configurations, or characteristics may be combined in any suitable manner in one or more embodiments.

The terms “above”, “over”, “to”, “between”, “spanning” and “on” as used herein may refer to a relative position of one layer with respect to other layers. One layer “above”, “over”, “spanning” or “on” another layer or bonded “to” or in “contact” with another layer may be directly in contact with the other layer or may have one or more intervening layers. One layer “between” layers may be directly in contact with the layers or may have one or more intervening layers.

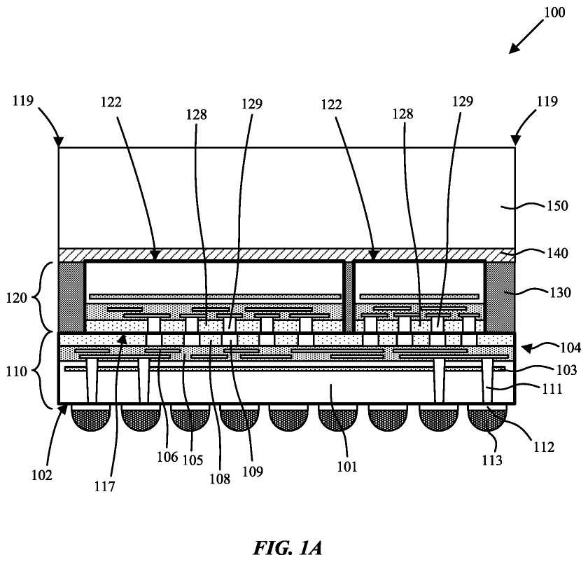

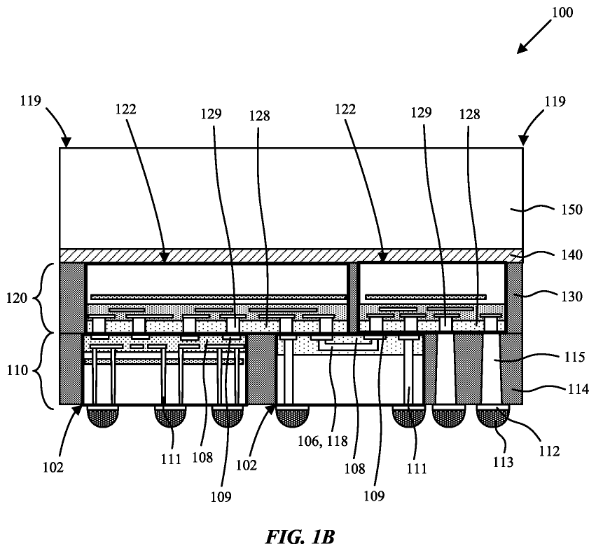

Referring now to FIGS. 1A-1B a cross-sectional side view illustrations are provided of semiconductor package 100 structures including a first package level 110 a second package level 120 including one or more second-level chiplets 122, and a heat spreader 150 bonded to the second package level with a metallic layer 140. As shown, straight package sidewalls 119 can span the first package level 110, the second package level 120, the metallic layer 140 and the heat spreader 150. For example, the straight package sidewalls 119 may be formed during singulation of one or more reconstituted package levels using a suitable technique such as wafer sawing, etching, etc.

The first package level 110 may include a planarized top surface 117 suitable for direct bonding of the second package level 120 (e.g. WoW) or one or more chiplets 122 (e.g. CoW) within the second package level 120. The first package level 110 may be an interposer substrate, such as with 2.5D packaging, or include one or more first-level chiplets 102, such as with 3D packaging. In the particular embodiments illustrated in FIGS. 1A-1B the first package level 110 includes one or more first-level chiplets 102, though this is exemplary and the CoW and WoW techniques in accordance with embodiments may be integrated with a variety of first package level structures. A variety of chiplets can be included in the first and/or second package levels depending upon application. Furthermore, the semiconductor packages in accordance with embodiments can facilitate die partitioning and process node optimization by integration of multiple chiplets into a single semiconductor package. Exemplary first-level chiplets 102 and second-level chiplets 122 can include a moderate power die (or low power) such as a system-on-chip (SOC), power management integrated circuit (PMIC), a low speed input/output (LSIO) die, high speed input/output (HSIO) die, and one or more high power dies such as a graphics processing unit (GPU), central processing unit (CPU), artificial intelligence (AI), machine learning logic, cache die, silicon interconnect to support die-to-die routing, and any combinations thereof. Thus, use of the term “chiplet” herein encompasses and ranges from dies with fully contained integrated circuits, partitioned dies including certain intellectual property (IP) blocks, logic dies, memory dies, to silicon interconnects, as well as silicon interconnects including logic and/or passive devices. Chiplets may additionally include an assembly of different components, can be heterogenous, and be hierarchically arranged. For example, a chiplet may include a separately formed layer(s) of an optical converter, or multiple attached components.

In the particular embodiment illustrated in FIG. 1A the semiconductor package 100 area is defined by the footprint of the first package level 110 (e.g. interposer, or the first-level chiplet 102 as illustrated), over which one or more second-level chiplets 122 can be integrated. In the particular embodiment illustrated in FIG. 1B the semiconductor package 100 can include multiple first-level chiplets 102, and thus area for the semiconductor package 100 is not defined by the size of a single first-level chiplet 102 (or interposer).

Referring to FIG. 1A, in the particular embodiment illustrated the semiconductor package 100 includes a first-level chiplet 102 within the first package level 110. The first-level chiplet 102 may include a semiconductor substrate 101 and back-end-of-the-line (BEOL) build-up structure 104. The BEOL build-up structure 104 can include one or more metal wiring layers 106 and dielectric layers 105, including a top oxide layer 108 and contact pads 109 for hybrid bonding. The BEOL build-up structure 104 may be formed over an active region 103 in the semiconductor substrate to connect with various devices (e.g. transistors, etc.) formed in the semiconductor substrate. A plurality of through vias 111 (e.g. through silicon vias (TSVs)) may also be formed through the semiconductor substrate 101 to connect the BEOL build-up structure 104 or active region to pads 112 on a back side of the first-level chiplet. It is to be appreciated that a first-level silicon interposer may be similarly formed, thus the illustration of FIG. 1A can be considered as including either a first-level chiplet 102 or interposer.

Referring now to FIG. 1B, in the particular embodiment illustrated semiconductor package 100 includes multiple first-level chiplets 102 within the first package level 110. The multiple first-level chiplets 102 may be embedded in a gap fill material 114 such as a polymer molding compound material, or oxide materials. For example, this may be accomplished through a wafer reconstitution process. Through vias 115 may additionally extend through the gap fill material 114 to provide electrical connection to the second package level 120. The through vias 115 may be through mold vias (TMVs), through oxide vias (TOVs), through dielectric vias (TDVs) or stand-alone printed circuit board (PCB) bars, etc. In an embodiment, the first-level chiplets 102 can include a silicon interconnect chiplet, including die-to-die routing 118 for connection between multiple second-level chiplets 122.

As shown in both FIGS. 1A-1B the second package level 120 can include multiple second-level chiplets 122 embedded in a gap fill material 130, which can be formed similarly as the gap fill material 114. Each of the second-level chiplets 122 may also include a top oxide layer 128 and contact pads 129 for hybrid bonding with the first package level 110. In accordance with embodiments, the second-level chiplets 122 may be bonded with the first package level 110 using a suitable technique such as chip-on-wafer (CoW) bonding. Alternatively, the second package level 120 can be bonded with the first package level 110 using a suitable technique such as wafer-on-wafer (WoW) bonding. In both techniques hybrid bonding may be used to form oxide-oxide and metal-metal bonds (copper-copper bonds, gold-gold bonds, etc.) or alternatively thermocompression bonding may be used to form the metal-metal bonds.

In accordance with embodiments, a heat spreader 150 is bonded to the second package level 120 with a metallic layer 140. The heat spreader 150 may be formed of a variety of thermally conductive materials, including metal, silicon, etc. In a particular embodiment the heat spreader 150 is formed from a silicon substrate, which can optionally be utilized during fabrication as a carrier wafer during CoW or WoW bonding. As such, the heat spreader 150 may be diced/singulated along with the semiconductor package such that the semiconductor package includes straight package sidewalls 119 spanning the first package level 110, the second package level 120, the metallic layer 140, and the heat spreader 150.

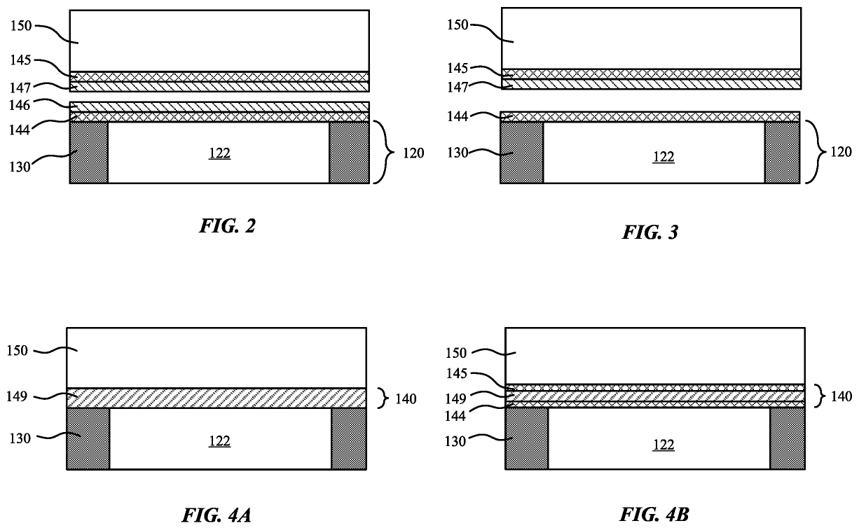

In accordance with embodiments the heat spreader 150 may be bonded using transient liquid phase (TLP) bonding where one or more intermetallic compounds are formed by interdiffusion of bonding layers. Referring now to FIGS. 2-3 schematic cross-sectional side view illustrations are provided of multiple bonding layers prior to bonding a heat spreader with a second package level in accordance with embodiments. As shown, bottom and top metal bonding layers 144, 145 may be first deposited onto the second package level 120 and the heat spreader 150, respectively. For example, the bottom metal bonding layer 144 may be deposited directly onto the one or more second-level chiplets 122 and gap fill material 130. Top metal bonding layer 145 may be deposited directly onto a silicon substrate as the heat spreader 150. Bottom and top metal bonding layers 144, 145 may be formed by first depositing a seed layer, then bulk growth or deposition using a suitable technique. The bottom and top metal bonding layers 144, 145 may be formed of a material such as Cu, Al, Ag, and Au.

This may be followed by deposition of one or more second metal bonding layers 146, 147 on either or both of the first metal bonding layers 144, 145. The second metal bonding layer(s) may be formed of a material such as In or Sn, characterized by a lower melting temperature than the bottom and top metal bonding layers. Lower melting temperatures, such as below 235° C., may facilitate processability. The two substrates may then be brought together under heat and pressure to reflow the second metal bonding layer(s) where the second metal bonding layer(s) diffuse into the bottom and top metal bonding layers 144, 145 causing isothermal solidification and the formation of one or more intermetallic compounds characterized by a higher melting temperature than the bonding temperature (and hence higher than the melting temperature of the second bonding layer(s). Thus, the intermetallic compound(s) completely consumes the second bonding layer(s). In an embodiment, the intermetallic compound(s) include Cu₃Sn.

Referring now to FIG. 4A, in an embodiment the top and bottom metal bonding layers 146, 147 (and seed layers) are completely consumed by the intermetallic compound(s), and the intermetallic compound(s) 149 are in direct contact with the heat spreader 150 and the second package level 120 (e.g. the plurality of second-level chiplets 122 and gap fill material 130). The second metal bonding layer(s) may also be completely consumed without completely consuming the bottom or top metal bonding layers 144, 145 as shown in FIG. 4B, where a layer of intermetallic compound(s) 149 is shown between remaining thicknesses of the bottom and top metal bonding layers 144, 145.

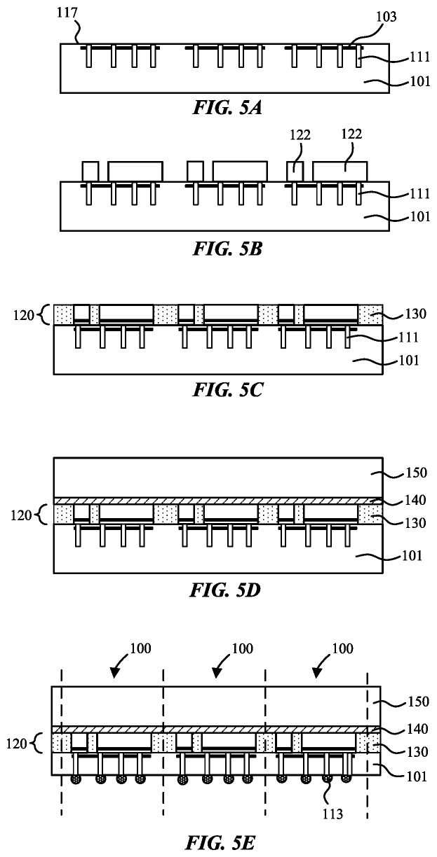

Referring now to FIGS. 5A-5E schematic cross-sectional side view illustrations are provided of a method of forming a semiconductor package with CoW chiplet bonding and an integrated heat spreader in accordance with an embodiment. In particular, the process sequence may be utilized to form a semiconductor package 100 such as that of FIG. 1A. It is to be appreciated however, that other processing sequences may be used to form the semiconductor package 100 of FIG. 1A, such as a sequence including WoW bonding of the second package level 120. As shown in FIG. 1A, the sequence may begin with a semiconductor substrate 101, such as silicon wafer, including optional active regions 103 and through vias 111 at least partially through the semiconductor substrate 101. A plurality of second-level chiplets 122 can then be bonded to the planarized surface 117, for example with TCB or hybrid bonding. This may be followed by deposition of a gap fill material 130, such as oxide, nitride (e.g. SiN) or organic molding compound and optionally planarizing to expose the back sides of the chiplets 122 as shown in FIG. 5C. The heat spreader 150 can then be bonded to the second package level 120 with metallic layer 140 using TLP bonding as shown in FIG. 5D. In an embodiment, the heat spreader 150 is a silicon carrier substrate that can provide mechanical support for the following processes. The semiconductor substrate 101 may then be thinned to expose the through vias 111, followed by formation of contact pads and solder bumps 113 as shown in FIG. 5E. The stack-up may then be singulated into multiple semiconductor packages 100 as shown with the dashed lines.

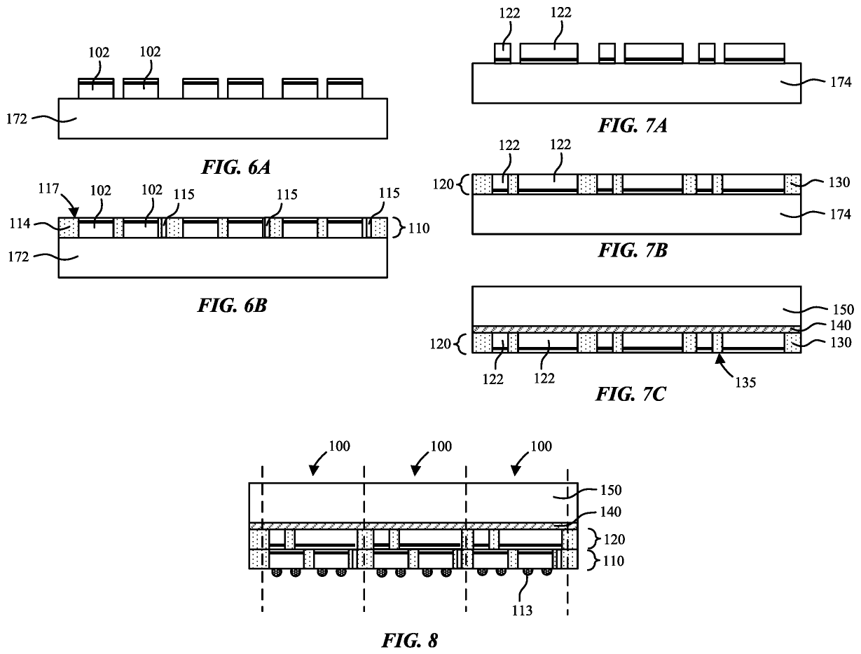

Referring now to FIGS. 6A-6B, FIGS. 7A-7C, and FIG. 8 schematic cross-sectional side view illustrations are provided of a method of forming a semiconductor package with reconstituted WoW bonding and an integrated heat spreader in accordance with an embodiment. In particular, the process sequence may be utilized to form a semiconductor package 100 such as that of FIG. 1B. It is to be appreciated however, that other processing sequences may be used to form the semiconductor package 100 of FIG. 1B, such as a sequence including CoW bonding of the first-level chiplets 102 or second-level chiplets 122 onto a reconstituted package level.

FIGS. 6A-B are schematic cross-sectional side view illustrations of a method of forming a reconstituted first package level 110 in accordance with an embodiment. As shown in FIG. 6A, the sequence may begin with mounting first-level chiplets 102 into a carrier substrate 172. In the particular embodiment illustrated the first-level chiplets 102 are mounted face up, though they can also be mounted face down, for example where one is thinner than the other. A gap fill material 114 such as an oxide or organic molding compound material is then formed over the first-level chiplets 102 as shown in FIG. 6B. Through vias 115 may also be formed through the gap fill material 114, or formed (e.g. as copper pillars) prior to the gap fill material 114. A top surface 117 may then be planarized to expose contact pads 109 of the first package level 110, and optionally through vias 115, and condition the top surface 117 for TCB or hybrid bonding. Where the first-level chiplets 102 are alternatively placed face down, then the original carrier substrate 172 can be removed after formation of the gap fill material, followed by attaching a second carrier substrate on the opposite side, removal of the original carrier substrate 172, and planarizing the top surface 117.

FIGS. 7A-7C are schematic cross-sectional side view illustrations of a method of forming a reconstituted second package level 120 with integrated heat spreader in accordance with an embodiment. As shown in FIG. 7A, the sequence may begin with mounting second-level chiplets 122 into a carrier substrate 174. In the particular embodiment illustrated the second-level chiplets 122 are mounted face down, though they can also be mounted face up. A gap fill material 130 such as an oxide, nitride (e.g. SiN) or organic molding compound material is then formed over the second-level chiplets 122 as shown in FIG. 7B. This may be followed by thinning to expose the back sides of the second-level chiplets 122. A heat spreader 150 can then be bonded to the second package level 120 with metallic layer 140 using TLP bonding as shown in FIG. 7C. In an embodiment, the heat spreader 150 is a silicon carrier substrate that can provide mechanical support for the following processes. The carrier substrate 174 may then be removed, followed by planarization of surface 135 to expose contact pads 129 on the second package level 120, and condition the surface 135 for TCB or hybrid bonding.

Referring now to FIG. 8 the reconstituted package levels can then be bonded to one another with WoW bonding. Additional processing such as addition of solder bumps 113 or Cu pillar bumps may be performed, followed by singulation into semiconductor packages 100. It is to be appreciated that while WoW bonding is illustrated, each of the reconstituted package levels could also be used to support CoW bonding of chiplets from the other package level.

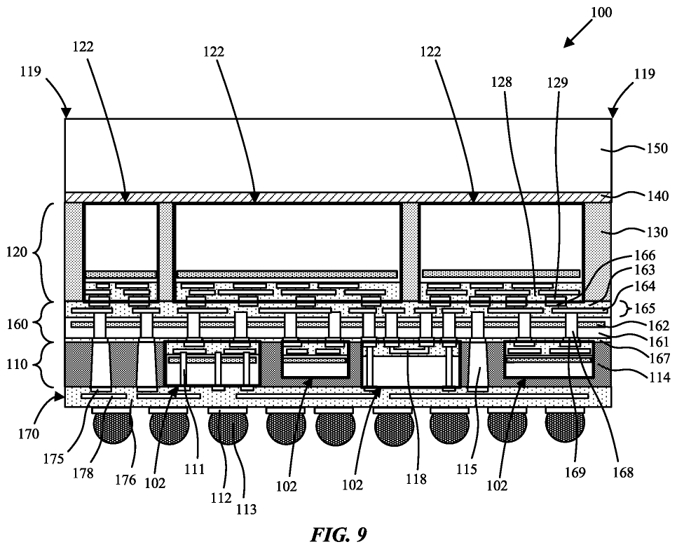

FIG. 9 is a schematic cross-sectional side view illustration of a semiconductor package 100 with intermediate interposer 160 and integrated heat spreader 150 in accordance with an embodiment. The semiconductor package 100 illustrated in FIG. 9 is similar to the semiconductor package illustrated in FIG. 1B, including multiple chiplets in each of the first package level 110 and second package level 120. The embodiment illustrated in FIG. 9 additionally illustrates an intermediate interposer 160 to which the multiple chiplets or package levels can be TCB or hybrid bonded to. The intermediate interposer may provide additional routing area, allowing for die partitioning and process node optimization, as well as flexibility for power delivery and integration of passive devices into the semiconductor package.

The intermediate interposer 160 in accordance with embodiments can include a bulk silicon layer 161 and an interposer BEOL build-up structure 165 formed similarly as those described for the chiplets in the first and second package levels, including one or more dielectric layers 163 and metal wiring layers 164. A topmost dielectric layer may be an oxide layer. A planarized surface may extend across the topmost dielectric layer and landing pads 166 to facilitate hybrid bonding. Similarly, a back-side oxide layer 167 and contact pads 169 with a planarized surface may be formed on the underside of the bulk silicon layer 161 for hybrid bonding with components in the first package level 110. A plurality of through silicon vias 168 can extend through the bulk silicon layer 161 (and back-side oxide layer 167) to the BEOL build-up structure. The intermediate interposer 160 may additionally include a plurality of devices 162, including passive devices such as MIM capacitors or trench capacitors, or even active devices such as transistors. In an embodiment, the intermediate interposer includes an array of trench capacitors. Alternative materials may also be used in place of the bulk silicon layer 161, such as glass or other non-silicon materials.

The semiconductor package 100 of FIG. 9 may be fabricated using a variety of processing sequences, including CoW and WoW techniques for either or both of the first package level 110 and second package level 120 as previously described. Also shown in FIG. 9 is an optional backside redistribution layer (RDL) 170 which may be formed on the first package level 110. The backside RDL may include contact pads 175 for connection to the first package level 110, as well as one or more metal routing layers 178 and dielectric layers 176. Pads 112 as previously described may be included in the backside RDL 170.

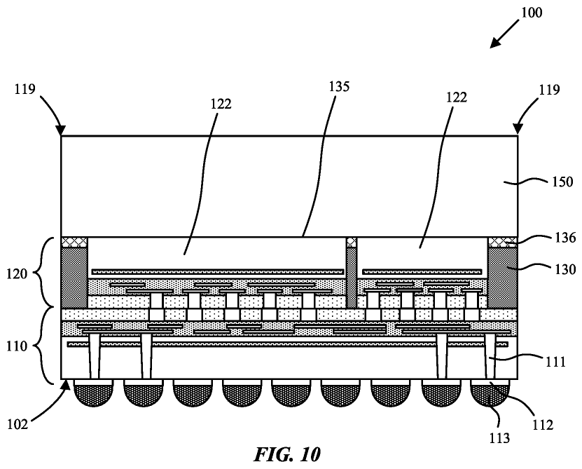

Up until this point semiconductor packages 100 have been described in which a heat spreader 150 is integrated with TLP bonding. In an alternative configuration illustrated in FIG. 10, a multiple layer gap fill may be utilized to facilitate silicon-silicon bonding with activated surfaces. In interest of conciseness, FIG. 10 is similar to the embodiment illustrated in FIG. 1A where gap fill material 130 does not entirely cover each second-level chiplet 122. In the illustrated embodiment, a capping gap fill material 136 may be formed over the bulk gap fill material 130, followed by planarization. The capping gap fill material 136 may be formed of silicon, such as an amorphous silicon or semicrystalline silicon material. After surface activation, the heat spreader 150 (silicon wafer) can be bonded to the planarized surface 135 of silicon materials including capping gap fill material 136 and chiplets 122.

The various semiconductor packages in accordance with embodiments can be assembled utilizing bonding techniques such as fusion bonding, TCB, and hybrid bonding to achieve minimum bump pitch (e.g. contact pad), such as in the range of 10 μm. Furthermore, CoW and WoW bonding can be utilized to form the multiple package levels. CoW and WoW bonding can also be implemented with reconstituted wafer structures.

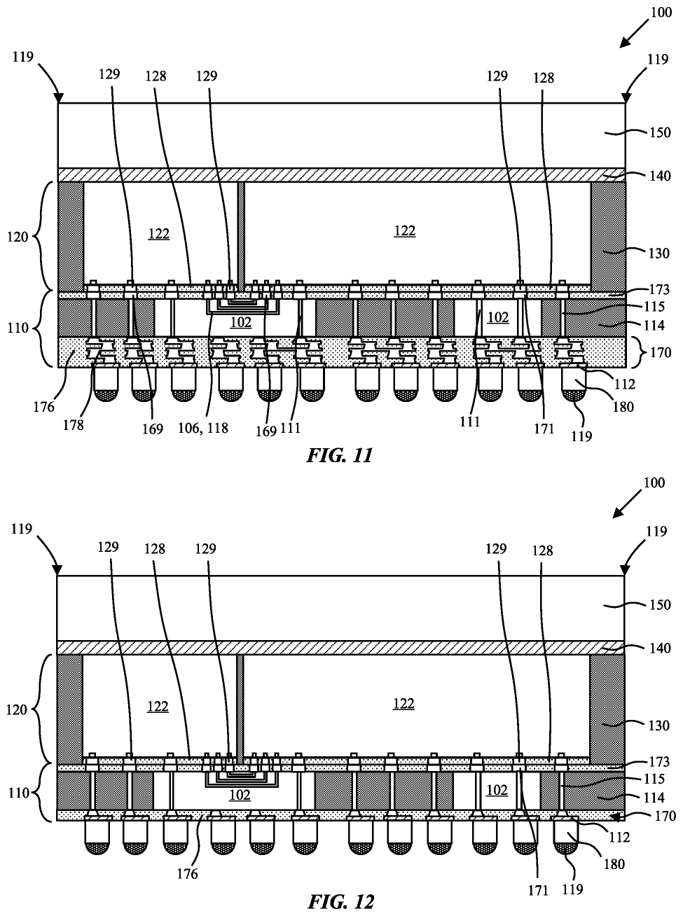

FIGS. 11-12 are schematic cross-sectional side view illustrations of semiconductor packages formed with chip-on-reconstituted wafer or reconstituted wafer-on-reconstituted wafer processing sequences in accordance with embodiments. Similar to previously described embodiments, the semiconductor package 100 can include a first package level 110 including one or more first-level chiplets 102 and a second package level 120 also including one or more second level chiplets 122. In accordance with embodiments at least a portion of the first package level 110 is hybrid bonded with at least a portion of the second package level 120. For example, this can be with CoW hybrid bonding of the first-level chiplets 102, CoW hybrid bonding of the second-level chiplets 122, or WoW hybrid bonding of the first and second package levels. Each of such CoW and WoW hybrid bonding can be onto reconstituted wafer structures including either or both of the first and second package levels.

Similar to other embodiments, the first package level 110 optionally includes a backside RDL 170 including one or more metal routing layers 178 and dielectric layers 176 and pads 112. The multiple first-level chiplets 102 may be embedded in a gap fill material 114 such as a polymer molding compound material, or oxide materials. For example, this may be accomplished through a wafer reconstitution process. Through vias 115 may additionally extend through the gap fill material 114 to provide electrical connection to the second package level 120. The through vias 115 may be through mold vias (TMVs), through oxide vias (TOVs), through dielectric vias (TDVs) or stand-alone printed circuit board (PCB) bars, etc. In an embodiment, the first-level chiplets 102 can include a silicon interconnect chiplet, including die-to-die routing 118 for connection between multiple second-level chiplets 122. In an embodiment, the first-level chiplets 102 can include a chiplet with through vias 111 for electrical connection with the optional backside RDL 170 or pads 112. A plurality of metal bumps 180 may optionally be formed on pads 112, and topped with solder tips 186. Alternatively, solder bumps can be utilized in place of the metal bumps 180 and solder tips 186.

Similar to other embodiments, a heat spreader 150 may optionally be bonded to the second package level 120 with a metallic layer 140. The semiconductor package 100 may include straight package sidewalls spanning the heat spreader 150, the metallic layer 140, the second package level 120 and the first package level 110.

In the illustrated embodiment a common insulator layer 173 is shown as being a part of the first package level 110. The common insulator layer 173 may additionally be patterned to include metal contact plugs 171, which provide electrical connection. In such a configuration, the second-level chiplets 122 can be hybrid bonded to the common insulator layer 173 and metal contact plugs 171 of the first package level 110, for example with CoW or WoW bonding. The common insulator layer 173 can alternatively be part of the second package level 120 to support hybrid bonding of the first-level chiplets 102 with CoW or WoW bonding. In yet another variation, each of the first package level 110 and the second package level 120 can include a common insulator layer 173 and metal contact plugs 171 for WoW bonding.

In a specific embodiment, the second level chiplets 122 cover a larger area than the first-level chiplets 102. This can accommodate the through vias 115 in the first package level 110. As such, the common insulator layer 173 may be located as part of the first package level 110 to provide additional area for oxide-oxide bonding of the second level chiplets 122. Upon singulation, the semiconductor packages 100 includes straight package sidewalls spanning the first gap fill material 114 of the first package level, the common insulator layer 173, and the second gap fill material 130 of the second package level. Where a heat spreader 150 is attached, the straight sidewalls may additionally span the metallic layer 140 and the head spreader 150.

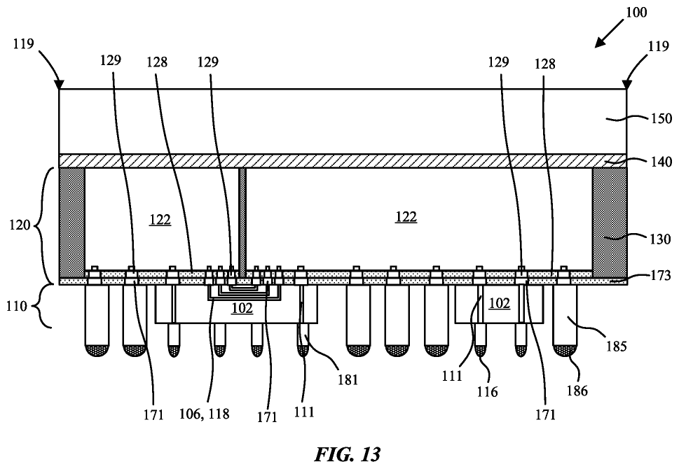

FIG. 13 is a schematic cross-sectional side view illustration of a semiconductor package formed with a chip-on-reconstituted wafer processing sequence in accordance with an embodiment. In the embodiment illustrated in FIG. 13 the one or more first-level chiplets 102 are hybrid bonded to the second package level 120, and optionally to the common insulator layer 173 and metal contact plugs 171. A plurality of metal pillars 185 can extend away from the second package level 120 and laterally adjacent to the one or more first-level chiplets 102. The metal pillars 185 may have a height that extends past a thickness of the first-level chiplets 102 to support bonding of the semiconductor package 100 to another routing substrate. In an embodiment a plurality of micro-pillars 181 can extend away from the back side(s) of one or more of the first-level chiplets 102. The micro-pillars 181 may have a width that is less than the metal pillars 185. Solder tips 186 and micro solder tips 116 can be applied to the plurality of metal pillars 185 and micro-pillars 181 for bonding. Similar to other embodiments, a heat spreader 150 may optionally be bonded to the second package level 120 with a metallic layer 140.

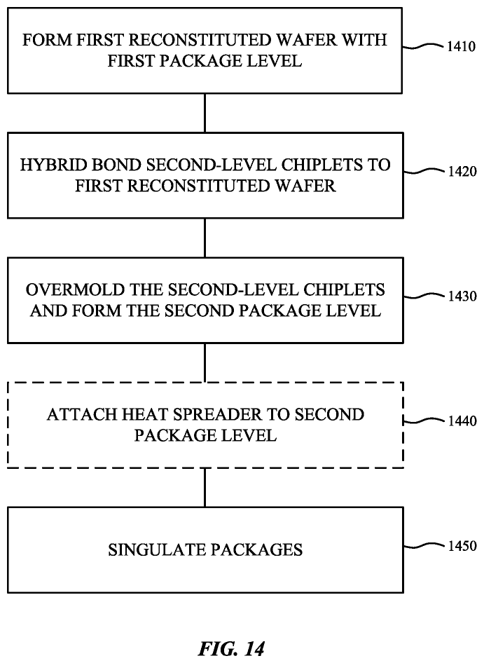

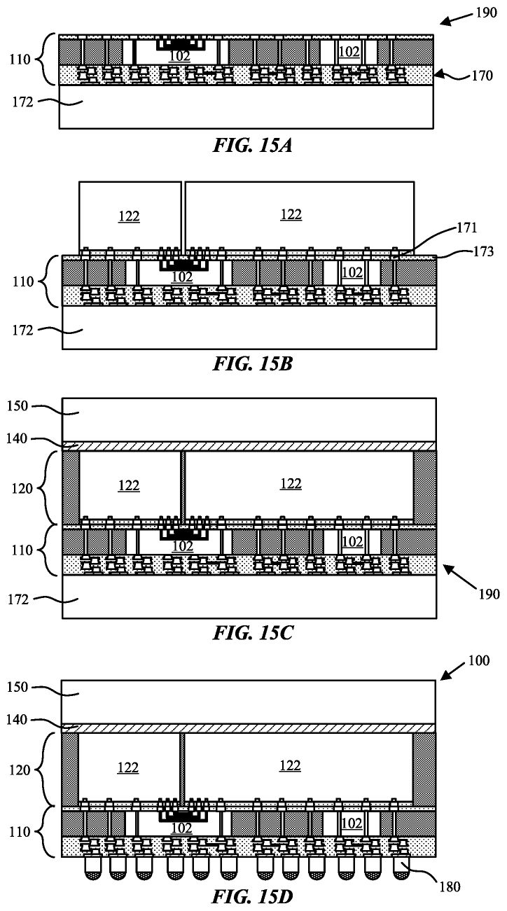

Referring now to FIG. 14 and FIGS. 15A-15D, FIG. 14 is a process flow of a semiconductor package formed with a chip-on-reconstituted wafer processing sequence in accordance with an embodiment; FIGS. 15A-15D are schematic cross-sectional side view illustrations of a semiconductor package similar to at least FIGS. 11-12 formed with a chip-on-reconstituted wafer processing sequence in accordance with an embodiment. In the interest of clarity and conciseness, the following description of FIG. 14 and FIGS. 15A-15D are discussed concurrently.

At operation 1410 a first reconstituted wafer 190 is formed including a first package level 110. The wafer reconstitution process of operation 1410 may be similar to that described with regard to FIGS. 6A-6B, and may include first forming optional backside RDL 170 on the carrier substrate 172 as shown in FIG. 15A. At operation 1420 the one or more second-level chiplets 122 are hybrid bonded to the first reconstituted wafer 190. As shown in FIG. 15B, the second-level chiplets 122 may be hybrid bonded to the optional insulator layer 173 (oxide-oxide bonds) and metal contact plugs 171 (metal-metal bonds). This may be followed by overmolding the second-level chiplets 122 with a gap fill material 130 at operation 1430 to form the second package level 120. A heat spreader 150 can then optionally be bonded to the second package level 120 with metallic layer 140 at operation 1440 using TLP bonding as shown in FIG. 15C.

As shown in FIG. 15D, the carrier substrate 172 may then be removed followed by formation of metal bumps 180 and solder tips, and singulation of multiple semiconductor packages 100 from the reconstituted wafer stack-up at operation 1450.

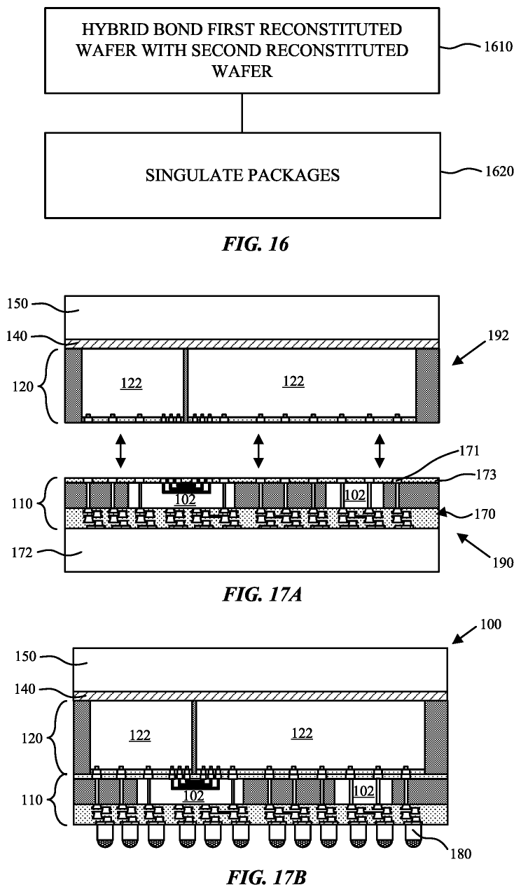

Referring now to FIG. 16 and FIGS. 17A-17B, FIG. 16 is a process flow of a semiconductor package formed with a reconstituted wafer-on-reconstituted wafer processing sequence in accordance with an embodiment; FIGS. 17A-17B are schematic cross-sectional side view illustrations of a semiconductor package similar to at least FIGS. 11-12 formed with a reconstituted wafer-on-reconstituted wafer processing sequence in accordance with an embodiment. In the interest of clarity and conciseness, the following description of FIG. 16 and FIGS. 17A-17B are discussed concurrently.

As shown in FIG. 17A at operation 1610 a first reconstituted wafer 190 is hybrid bonded with a second reconstituted wafer 192. For example, the first reconstituted wafer 190 can be formed similar to the sequence illustrated and described with regard to FIGS. 6A-6B, while the second reconstituted wafer 192 can be formed similar to the sequence illustrated and described with regard to FIGS. 7A-7C. Additional layers may optionally be included such as common insulator layer 173 and backside RDL 170, for example.

In an embodiment, forming the first package level 110 of the first reconstituted wafer 190 includes forming a common insulator layer 173, and the one or more second-level chiplets 122 are oxide-oxide bonded with the common insulator layer 173 during reconstituted WoW bonding. The common insulator layer 173 and metal contact plugs 171 can alternatively be formed on the second package level 120, or on both the first package level and the second package level to facilitate hybrid bonding. In an embodiment, a heat spreader 150 is optionally attached to the second package level 120 during formation of the second reconstituted wafer 192.

As shown in FIG. 17B, the carrier substrate 172 may then be removed followed by formation of metal bumps 180 and solder tips, and singulation of multiple semiconductor packages 100 from the reconstituted wafer stack-up at operation 1620.

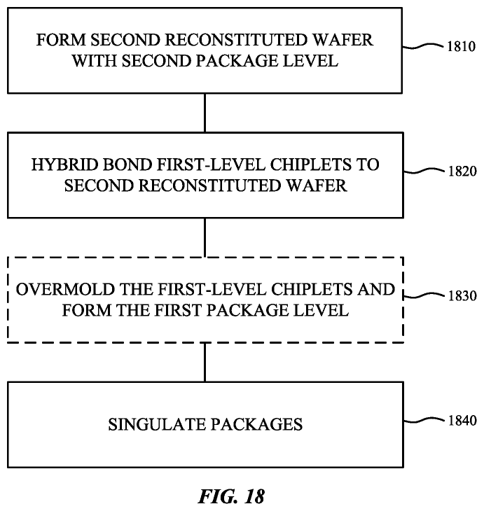

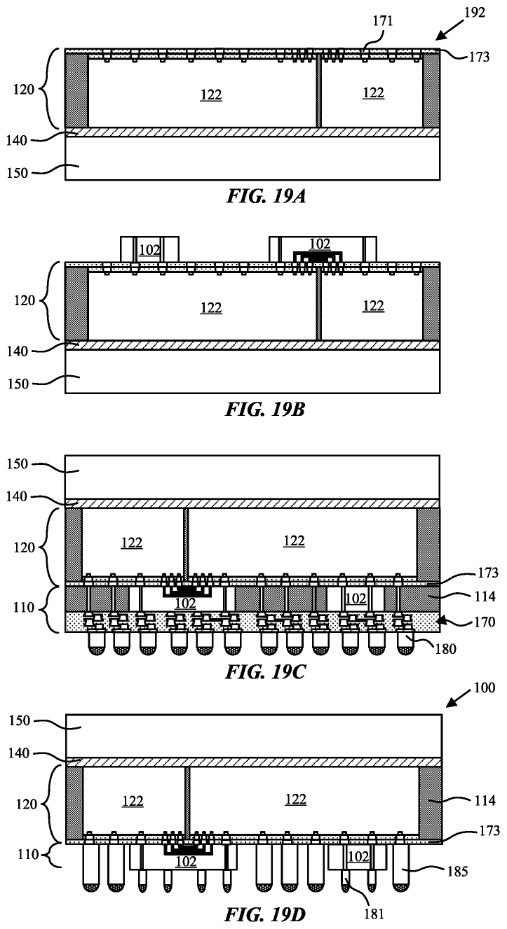

Referring now to FIG. 18 and FIGS. 19A-19D, FIG. 18 is a process flow of a semiconductor package formed with a chip-on-reconstituted wafer processing sequence in accordance with an embodiment; FIGS. 19A-19D are schematic cross-sectional side view illustrations of a semiconductor package similar to at least FIGS. 11-13 formed with a chip-on-reconstituted wafer processing sequence in accordance with an embodiment. In the interest of clarity and conciseness, the following description of FIG. 14 and FIGS. 15A-15D are discussed concurrently.

At operation 1810 a second reconstituted wafer 192 is formed including a second package level 120. The wafer reconstitution process of operation 1810 may be similar to that described with regard to FIGS. 7A-7C, and may optionally include forming common insulator layer 173 and metal contact plugs 171 as shown in FIG. 19A. At operation 1820 the one or more first-level chiplets 102 are hybrid bonded to the second reconstituted wafer 192. As shown in FIG. 19B, the first-level chiplets 102 may be hybrid bonded to the optional insulator layer 173 (oxide-oxide bonds) and metal contact plugs 171 (metal-metal bonds).

Referring to FIG. 19C at operation 1830 the first-level chiplets 102 may optionally be overmolded with a gap fill material 130 to form the first package level 110. This may optionally include formation of backside RDL 170. This may be followed by formation of metal bumps and solder tip, and singulation of multiple semiconductor packages 100 from the reconstituted wafer stack-up at operation 1840.

Referring to FIG. 19D, in an embodiment the first-level chiplets 102 are not overmolded. In the illustrated embodiment, a plurality of metal pillars 185 are formed laterally adjacent to the one or more first-level chiplets 102 and extending away from the second package level. A plurality of micro-pillars 181 can also be formed extending away from the back side(s) of one or more of the first-level chiplets. This may be followed by application of solder tips and micro solder tips, and singulation of multiple semiconductor packages 100 at operation 1840.

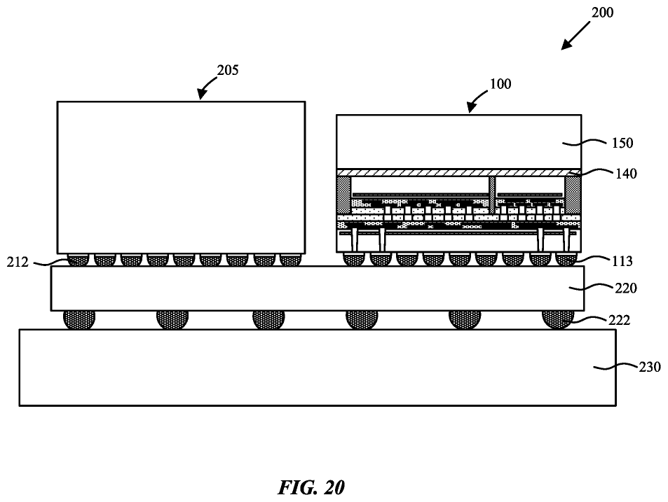

Referring now to FIG. 20, the various semiconductor packages 100 in accordance with embodiments may be integrated into a multi-chip module system 200. For example, such a system may include a module substrate 220 upon which the semiconductor package 100 and another component 205 such as memory package are flip chip bonded using solder bumps 113, 212. The module substrate 220 in turn may be bonded to a printed circuit board 230 using a suitable technique such as solder balls 222, or pins.

Up until this point various semiconductor package structures and assembly techniques have been described in which fusion bonding, TCB, and hybrid bonding can be utilized, with both CoW and WoW bonding techniques, to achieve fine bump pitch in multiple package levels. The various package structures and assembly techniques are also compatible with electromagnetic field communication structures such as capacitive, magnetic, or photonic coupling to communicate across dielectric layers, or even thin metal layers. Photonic coupling may include photonic waveguides or photonic wires, for example, as well as electrical-to-optical (EO) converters and optical-to-electrical (OE) converters. An EO converter may include conversion electronics and any suitable optical transmitter such as laser, light emitting diode, or other light source, modulator, etc. An OE converter may include an optical receiver such as a photodetector (avalanche photodiode, p-i-n photodiode, etc.) and conversion electronics. One or more optical repeater structures may additionally be included in the optical paths to receive, amplify, and then re-transmit the optical signals. One example is an optical amplifier (e.g. semiconductor optical amplifier). Other repeaters may be electrical/optical that can be integrated into active silicon connected to the optical paths with a variety of features such as logic, flops, cache, memory compressors and decompressors, controllers, local processing elements, etc. The OE/EO converters can also include optical mutliplexers, demultiplexers.

The chiplets described herein may additionally include an assembly of different components, can be heterogenous, and be hierarchically arranged. For example, a chiplet may include a separately formed layer(s) of an optical converter, or multiple attached components.

The optical paths produced by the waveguides or photonic wires may be rigid or flexible. In an exemplary embodiment, waveguides are formed of a suitable material, such as oxide or nitride, that is readily integrated into semiconductor device fabrication and packaging. Vertical photonic communication, such as across CoW or WoW bonded surfaces, can be further negotiated using optical vias, grating couplers, mirrors, prisms, or additional waveguides or photonic wire bonds.

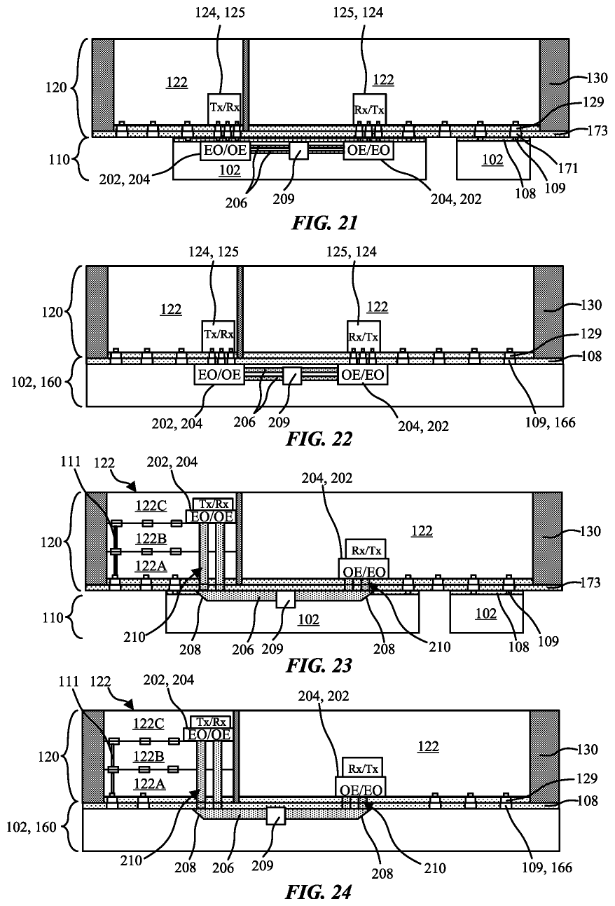

Referring now to FIGS. 21-29 schematic cross-sectional side view illustrations are provided of exemplary semiconductor package structures with optical interconnects in accordance with embodiments. The semiconductor package structures may correspond to the semiconductor structures previously described herein, and as such, the illustrational detail is focused on the optical interconnect structures rather than common shared features previously described herein.

The particular embodiment illustrated in FIG. 21 may be similar to those illustrated and described with regard to FIGS. 1B and 11-13 for example, including a first package level 110 with one or more first-level chiplets 102 and a second package level 120 with one or more second-level chiplets 122. In interest of not obscuring the subject matter of the optical paths, the illustrational detail is focused on the optical interconnect structures rather than common shared features previously described herein, which may be included. A common insulator layer 173 may be formed as part of the first package level 110 or the second package level 120. In the particular embodiment illustrated, the common insulator layer 173 is formed as part of the second package level 120, though this is exemplary. In the particular embodiment illustrated an optical path is entirely contained within a first-level chiplet 102. Similarly, an optical path could be entirely contained within a second-level chiplet 122. In the exemplary illustration, various second-level chiplets 122 can include transceivers (Tx) 124 and receivers (Rx) 125 that may be in electrical connection with contact pads 129 of the second-level chiplets 122. Similar to previously described process flows, the one or more second-level chiplets 122 can be encapsulated in a gap fill material 130, and the common insulator layer 173 and metal contact plugs 171 are formed over the face sides of the one or more second-level chiplets 122 and the gap fill material, with the metal contact plugs 171 aligned with the contact pads 129. The first-level chiplets 102 can then be fusion bonded, TCB, or hybrid bonded to the common insulator layer 173 and metal contact plugs 171. For example, the top oxide layer 108 and contact pads 109 of the first-level chiplets 102 can be hybrid bonded to the common insulator layer 173 and metal contact plugs 171. In the illustrated embodiment, the Tx/Rx and Rx/Tx are in electrical communication with optical converters in a first-level chiplet 102, and more specifically electrical-to-optical (EO) converters 202 and optical-to-electrical (OE) converters 204. One or more optical interconnects 206 (e.g. waveguide, photonic wire) may then connect adjacent optical converters to provide an optical path. Such an optical path may provide short communication, or long reach communication, and is not limited to die-edge connections, and may provide core-to-core connection between dies, or opposite edges. A variety of configurations are possible. In some embodiments, one or more repeaters 209 may be included along the optical path, and be connected to the optical interconnect 206 to receive, amplify, and then re-transmit the optical signals. In an exemplary configuration a Tx 124 may be electrically connected to EO converter 202, which converts the electrical signal to an optical signal which is then transferred across the optical interconnect 206 (e.g. waveguide, photonic wire) to an OE converter 204, which transmits the optical signal to an electrical signal, which in turn is in electrical connection with the Rx 125 in a separate second-level chiplet 122. Complementary systems are also in place for reverse communication between the second-level chiplets 122.

It is to be appreciated that while die-to-die connection is illustrated and described as being though a first-level chiplet 102 to connect multiple second-level chiplets 122, that this may be reversed. Furthermore, while the optical communication path is described with a waveguide as the optical interconnect 206, this may be replaced with another suitable optical interconnect such as a photonic wire that is wire bonded to the corresponding EO and OE converters.

In an embodiment, a semiconductor package includes a first package level including a first-level chiplet, and a second package level including a first second-level chiplet and a second second-level chiplet. The first package level may be direct bonded (e.g. fusion bonding, TCB, hybrid bonded) with the second package level. The first-level chiplet may additionally include an electrical-to-optical (EO) converter electrically connected with the first second-level chiplet, an optical-to-electrical (OE) converter electrically connected with the second second-level chiplet, and an optical interconnect (e.g. waveguide, optical wire) that connects the EO converter and the OE converter. In a specific embodiment, the first package level is hybrid bonded with the second package level to facilitate electrical connection with the first-level chiplet, which may contain the optical path. In a specific embodiment, the first-level chiplet is oxide-oxide bonded (or dielectric-dielectric bonded) to a common insulator layer spanning across the first second-level chiplet and the second second-level chiplet.

Referring now to FIG. 22 a schematic cross-sectional side view illustration is provided of a semiconductor package structure with optical interconnects similar to the structures of FIGS. 1A and 9-10. In interest of not obscuring the subject matter of the optical paths, the illustrational detail is focused on the optical interconnect structures rather than common shared features previously described herein, which may be included. In such a configuration the second-level chiplets 122 may optionally be bonded to a first-level chiplet 102 or intermediate interposer 160. For example, the second-level chiplets 122 can be fusion bonded, TCB, or hybrid bonded to the top oxide layer 108 and contact pads 109 of the first-level chiplet 102, or dielectric layer 163 and landing pads 166 of the intermediate interposer 160. The optical interconnects may be similarly connected as previously described with regard to FIG. 21.

Referring now to FIGS. 23-24 schematic cross-sectional side view illustrations are provided of semiconductor package structures with optical interconnects similar to the structures of FIGS. 21-22, with different locations of the EO and OE converters. Like FIGS. 21-22, FIGS. 23-24 resemble those of FIGS. 1A-1B and 9-13. In interest of not obscuring the subject matter of the optical paths, the illustrational detail is focused on the optical interconnect structures rather than common shared features previously described herein, which may be included. In the particular embodiments, the EO converters 202 and OE converters 204 may be located with the second-level chiplets 122 while the optical interconnects 206 (waveguides or photonic wires) are located in the first-level chiplet 102 or intermediate interposer 160. Furthermore, optical vias 210 may optionally extend through any or all layers between the converters and the optical interconnects 206 to facilitate the optical path. For example, optical vias may be filled with a transparent material of specific refractive index.

As shown, in accordance with the various embodiments described herein the chiplets 122 may include a plurality of three dimensional (3D) stacked sub-chiplets (e.g. 122A, 122B, 122C, etc.). While three sub-chiplets are illustrated, it is to be appreciated this is exemplary, and embodiments may include two or more stacked sub-chiplets. In accordance with embodiments, the optical vias 210 may extend through one or more of the sub-chiplets, which may also be electrically connected with TSVs, contact pads, etc. In the illustrated embodiment, the optical path (through one or more optical vis 210 for example) may proceed through one or more of the stacked sub-chiplets. Each sub-chiplet may be similar to a chiplet as defined herein, and the 3D stack may be fusion bonded, TCB, or hybrid bonded. In this manner, the optical path (and optical interconnect) may extend to any sub-chiplet within the 3D stack. It is to be appreciated that the illustrated example of multiple stacked sub-chiplets is exemplary, and embodiments do not require multiple stacked sub-chiplets within a chiplet.

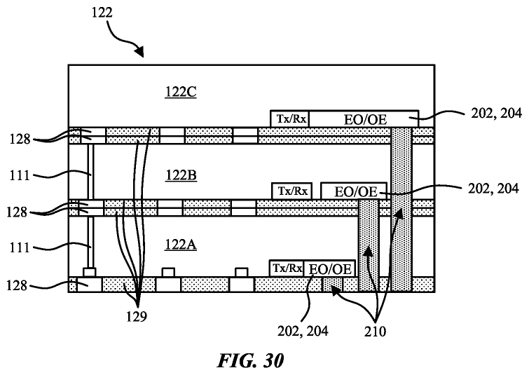

The optical path may connect all of the sub-chiplets (122A, B, C) or some permutations (e.g., 122A and 122C, or 122C as shown in the drawing). Further the optical paths may be shared, or separate, depending on EO/OE and waveguides and wavelengths. Referring briefly to FIG. 30, a schematic cross-sectional side view illustration is provided of a second-level chiplet 122 including multiple EO converters 202, EO converters 204, and optical vias 210 in accordance with an embodiment. In this manner, each sub-chiplet may include a corresponding transceiver and/or receiver, and converter. The illustrated optical vias 210 may be singular as shown, or multiples. The optical vias 210 may be bi-directional (for optical transmission and reception) or single directional. An array of optical vias 210 may be included to support communication with different wavelengths and/or to different sub-chiplets.

One or more mirrors 208, diffraction grating coupler, prism, etc. may also facilitate connecting the vertical optical path with the optical interconnect 206. In this manner, the optical paths may travel from the EO converters 202 through the optional optical vias 210 (or other intermediate dielectric/insulating layer), through the optical interconnect 206 (waveguide or photonic wire), back through optional optical vias (or other intermediate dielectric/insulating layer) and to the OE converters 204 located in a separate chiplet.

In an embodiment, a semiconductor package includes a first package level including a first-level chiplet, and a second package level including a first second-level chiplet and a second second-level chiplet. The first package level may be direct bonded (e.g. fusion bonded, TCB, hybrid bonded) with the second package level. In an embodiment, the first second-level chiplet includes an electrical-to-optical (EO) converter, and the second second-level chiplet includes an optical-to-electrical (OE) converter, and the first-level chiplet additionally includes an optical interconnect (e.g. waveguide, photonic wire) that is optically connected with the EO converter and the OE converter. In an embodiment, a first optical via optically connects the EO converter to the optical interconnect, and a second optical via that optically connects the optical interconnect to the OE converter. In a specific embodiment, the first-level chiplet is oxide-oxide bonded (or dielectric-dielectric bonded) to a common insulator layer spanning across the first second-level chiplet and the second second-level chiplet.

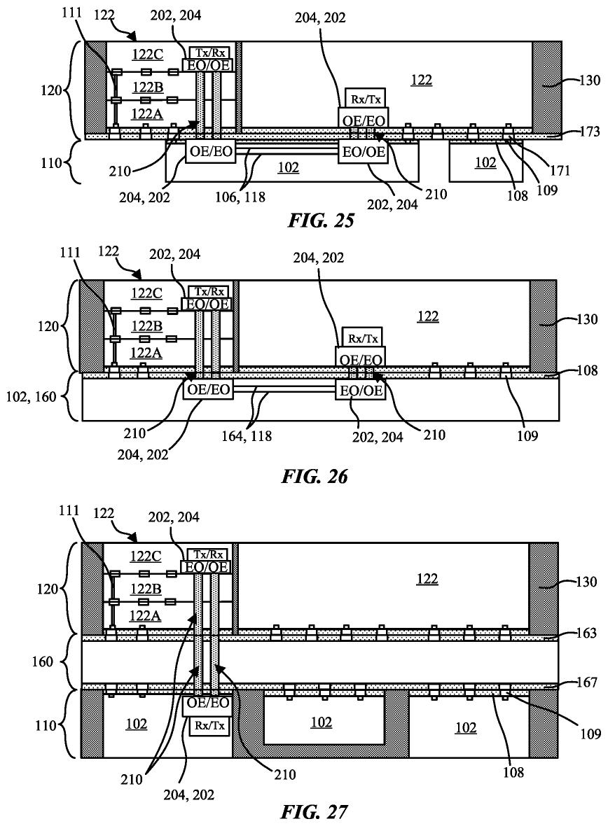

Referring now to FIGS. 25-27 schematic cross-sectional side view illustrations are provided of semiconductor package structures with optical interconnects similar to the structures of FIGS. 21-22 and FIGS. 23-24, with different locations of the EO and OE converters. Like FIGS. 21-24, FIGS. 25-27 resemble those of FIGS. 1A-1B and 9-13. In interest of not obscuring the subject matter of the optical paths, the illustrational detail is focused on the optical interconnect structures rather than common shared features previously described herein, which may be included. In such embodiments the optical paths may be much shorter, effectively bridging the vertical distance between chiplets in different package levels, as shown in FIGS. 25 and 27, or between a package level and intermediate interposer 160. The optical paths may also extend through one or more sub-chiplets 122A, 122B, 122C, etc. as previously described with regard to FIGS. 23-24, and FIG. 30. In the embodiment illustrated in FIG. 27, the optical path may proceed through optical vias 210 extending through the intermediate interposer 160.

In an embodiment, a semiconductor package includes a first package level including a first-level chiplet, and a second package level including a second-level chiplet. In an embodiment, the first-level chiplet includes an optical-to-electrical (OE) converter, and the second-level chiplet includes an electrical-to-optical (EO) converters. The semiconductor package may further include an optical via that optically connects the EO converter with the OE converter. For example, the optical via can extend through an intermediate interposer vertically between the first-level chiplet and the second-level chiplet, or one or more dielectric/insulating layers used for direct bonding of the package levels. Where an intermediate interposer is present, the first-level chiplet may be direct bonded with the intermediate interposer, and the second-level chiplet is also direct bonded with the intermediate interposer.

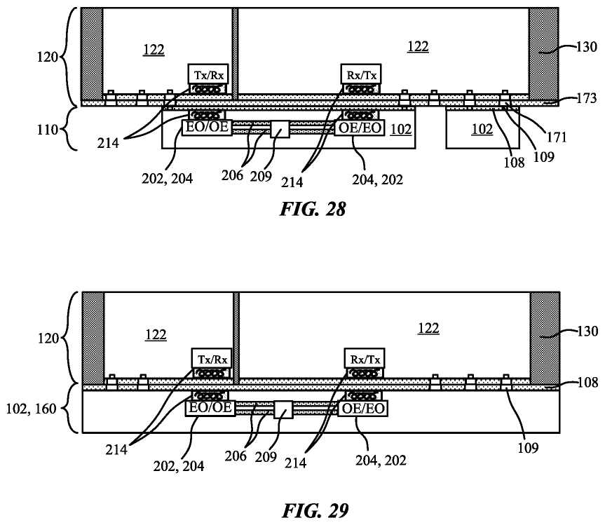

Referring now to FIGS. 28-29 schematic cross-sectional side view illustrations are provided of semiconductor package structures with optical interconnects similar to the structures of FIGS. 21-27, with different locations of the EO and OE converters. Like FIGS. 21-27, FIGS. 28-29 resemble those of FIGS. 1A-1B and 9-13. In interest of not obscuring the subject matter of the optical paths, the illustrational detail is focused on the optical interconnect structures rather than common shared features previously described herein, which may be included. In such embodiments short range communication paths (e.g less than 100 μm (magnetic, and less than 1-μm capacitive coupled)) can be achieved with various electromagnetic field communication structures with capacitive coupling, magnetic coupling, optical coupling. For example, the electromagnetic field communication structures 214 can include coils or capacitors to facilitate coupling, and may be vertically aligned. The electromagnetic field communication structures 214 can wireless communicate between the second-level chiplets 122 and the first-level chiplet(s) 102 or intermediate interposer 160. The electromagnetic field communication structures 214 within a first-level chiplet 102 or intermediate interposer 160, for example, can further be connected to EO converters 202 and OE converters, with the optical interconnect 206 connecting the converters.

It is to be appreciated that while the embodiments of FIGS. 21-29 are illustrated as separate semiconductor package structures that the various optical interconnects can be combined. Furthermore, the optical interconnects of FIGS. 21-29 may also be combinable with metal wiring paths described herein. In addition, while hybrid bonding is illustrated for the various chiplets of FIGS. 21-29, this is not required, and the chiplets may be fusion bonded or otherwise bonded with TCB without including metal-metal bonds therebetween. Furthermore, the chiplets within various package levels may include multiple 3D stacked sub-chiplets.

In utilizing the various aspects of the embodiments, it would become apparent to one skilled in the art that combinations or variations of the above embodiments are possible for forming reconstituted 3DIC packages and 3DIC packages with integrated heat spreaders. Although the embodiments have been described in language specific to structural features and/or methodological acts, it is to be understood that the appended claims are not necessarily limited to the specific features or acts described. The specific features and acts disclosed are instead to be understood as embodiments of the claims useful for illustration.

What is claimed is:

1. A semiconductor package comprising:
a first package level including a first-level chiplet or intermediate interposer;
a second package level including a first second-level chiplet and a second second-level chiplet;
wherein the first package level is direct bonded with the second package level; and
wherein the first-level chiplet or intermediate interposer includes an electrical-to-optical (EO) converter electrically connected with the first second-level chiplet, an optical-to-electrical (OE) converter electrically connected with the second second-level chiplet, and an optical interconnect that connects the EO converter and the OE converter.

2. The semiconductor package of claim 1, wherein the first-level chiplet is dielectric-dielectric bonded to a common insulator layer spanning across the first second-level chiplet and the second second-level chiplet, and metal-metal bonded to metal contact plugs extending through the common insulator layer.

3. The semiconductor package of claim 1, wherein the optical interconnect comprises a waveguide or photonic wire.

4. The semiconductor package of claim 1, wherein the EO converter is connected to a first electromagnetic field communication structure, and the first second-level chiplet includes a second electromagnetic field communication structure.

5. The semiconductor package of claim 4, wherein the first electromagnetic field communication structure and the second electromagnetic field communication structure are vertically aligned.

6. The semiconductor package of claim 5, wherein the first electromagnetic field communication structure and the second electromagnetic field communication structure are coils or capacitors.

7. A semiconductor package comprising:
a first package level including a first-level chiplet or intermediate interposer;
a second package level including a first second-level chiplet and a second second-level chiplet;
wherein the first package level is direct bonded with the second package level; and
wherein the first second-level chiplet includes an electrical-to-optical (EO) converter, and the second second-level chiplet includes an optical-to-electrical (OE) converter; and
wherein the first-level chiplet or intermediate interposer includes an optical interconnect that is optically connected with the EO converter and the OE converter.

8. The semiconductor package of claim 7, wherein the optical interconnect is selected from the group consisting of a waveguide and a photonic wire.

9. The semiconductor package of claim 8, further comprising a first optical via that optically connects the EO converter to the optical interconnect, and a second optical via that optically connects the optical interconnect to the OE converter.

10. The semiconductor package of claim 9, wherein the first second-level chiplet includes a plurality of sub-chiplets, and the first optical via extends through one or more of the plurality of sub-chiplets.

11. The semiconductor package of claim 7, wherein the first-level chiplet is oxide-oxide bonded to a common insulator layer spanning across the first second-level chiplet and the second second-level chiplet.

12. A semiconductor package comprising:
a first package level including a first-level chiplet or intermediate interposer;
a second package level including a second-level chiplet;
wherein the first-level chiplet or intermediate interposer includes an optical-to-electrical (OE) converter, and the second-level chiplet includes an electrical-to-optical (EO) converters; and
an optical via that optically connects the EO converter with the OE converter.

13. The semiconductor package of claim 12, wherein the first package level includes the first-level chiplet, and the intermediate interposer is vertically between the first-level chiplet and the second-level chiplet, and further comprising an optical via that through the intermediate interposer vertically between the first-level chiplet and the second-level chiplet.

14. The semiconductor package of claim 12, wherein the first package level includes the first-level chiplet, the first-level chiplet is direct bonded with the intermediate interposer, and the second-level chiplet is direct bonded with the intermediate interposer.

15. The semiconductor package of claim 12, wherein the second-level chiplet includes a plurality of sub-chiplets, and the optical via extends through one or more of the plurality of sub-chiplets.
